(19) United States
(12) Patent Application Publication
(10) Pub. No.: US 2011/0096553 A1
(43) Pub. Date: Apr. 28, 2011

(54) LED light distribution lens, LED lighting module having LED light distribustion lens and lighting equipment having LED lighting module

(75) Inventor: Teppei Shimokawa, Higashiosaka-shi (JP)

(73) Assignee: ENDO Lighting Corporation

(21) Appl. No.: 12/802,940

(22) Filed: Jun. 17, 2010

(30) Foreign Application Priority Data
Oct. 27, 2009 (JP) 2009-246359

(51) Int. Cl. F21V 5/04; H01L 33/58; G02B 17/00

(52) U.S. Cl. 362/311.02; 257/98; 359/727; 257/E33.067; 257/E33.056

(57) ABSTRACT

LED light distribution lens having a light emitting surface whose shape is circular in its plan view, which emits forward light from LED disposed in its center.

The LED light distribution lens is characterized by the construction of the emitting surface which is low at production cost and so designed as not to cause the diffuse reflection and unintended diffusion. Such emitting surface has a plural convex surfaces formed both in its radial and its circumferential directions in a manner that the convex surfaces surround the circumference of the LED and has continuous surfaces formed such that the boundary portions of the convex surfaces constitute the concave surfaces, thereby realizing expected light distribution based on design specification.

### TECHNICAL FIELD

The present invention relates to an LED light distribution lens, an LED lighting module having the LED light distribution lens and lighting equipment having the LED lighting module.

### BACKGROUND ART

Lighting equipment using an LED has been widely used as a light source with long life and low power consumption in these days. An LED distribution lens for use in such lighting equipment has been produced with many efforts in order to emit forward the light of LED efficiently.

FIG. 8 shows an example of an LED distribution lens for use in lighting equipment using an LED as a light source.

An LED distribution lens 100 in the figure has a light emitting surface 200 having a plurality of honeycomb cells 300 and the surface of the cell 300 is processed to be a convex shape so as to emit the light passing therethrough into a predetermined direction.

The following patent citation 1 describes an LED distribution lens having a central prism formed in the center of a lens body and focusing light from a light source within a specified angular range by refraction, and an outer ring prism standing on the circumference of the central prism to form a recess and leading in the light from the light source deviating from the specified angular range before focusing by total reflection.

The prior art describes that the light beams radiated sideward from an LED, as well as the light beams in the central part, can be focused and condensed entirely, thereby achieving high condensation efficiency.

### PRIOR ART CITATION

### Patent Citation

PATENT CITATION 1 Japanese patent publication No. 2002-43629-A

### DISCLOSURE OF INVENTION

### Technical Solution

However, the prior LED light, distribution lens 100 in FIG. 8 has the following problems.

FIG. 9 is a schematic view for explaining the problems, FIG. 9a shows an ideal mold and the sectional view of the cell of the LED light distribution lens formed with the mold, and FIG. 9b shows an actual mold and the sectional view of the cell of the LED light distribution lens formed with the mold.

According to a mold 400 forming the cell 300 in FIG. 9a, the configuration of the convex surface in sectional view is accurately ground in which each convex surface of the cells 300 and the boundary area between the cell 300 and the cell 300 are accurately formed when an edge 400a between the cells 300 is sharply formed. Therefore, the light transmitting a light emitting surface 200 can be emitted in a predetermined direction based on the design. Particularly the incident light between the cell 300 and the cell 300 is designed to have the largest output angle using a refraction phenomenon (refer to the arrow 500 showing a light path in FIG. 9a) and is an important place which determines the light diffusion degree, so that the cell 300 is required to be formed with the mold 400 having the sharp edge 400a.

However, the light emitting surface 200 is not actually processed with the mold 400 having an ideal sharp edge 400a. It is because the mold surface is generally ground after cutting procedure of the mold 400 and the edge 400a is also ground to be flat like the edge 400a shown in FIG. 9b and to be rounded. Thus, the boundary area 300a is apt to be formed between the cell 300 and the cell 300 as shown in a partially enlarged view in FIG. 8 and FIG. 9b and the output angle of the light transmitting the boundary area 300a becomes narrower than that of the designed angle (see the arrow 600 showing the light path in FIG. 9b).

In order to solve such a problem, the cutting accuracy of the mold 400 is tried to be improved by eliminating the polishing process of the mold 400, however, much cost and time are required for making the mold. In addition, even if the mold 400 is produced with much cost, the sharply pointed edge 400a is fragile and there remains a problem of short lifespan.

Further, the light emitting surface of the LED light distribution lens described in the patent citation 1 simply comprises a flat surface and the above-mentioned problem is not occurred, however, even if the light emitted into the center or sideward from the LED is focused, the emitting light cannot be controlled to cause wide light distribution on the light emitting surface, thereby causing nonuniform emission.

In view of the above-mentioned problems, the present invention has an object to provide an LED light distribution lens capable of light distribution as designed, an LED lighting module having the LED light distribution lens, and lighting equipment having the LED lighting module.

### Means to Solve the Problem

The present invention relates to an LED light distribution lens for emitting forward light of an LED disposed in the center thereof, the lens having a light emitting surface with a circular shape in plan view, wherein the light emitting surface has a plurality of convex surfaces both in its radial and its circumferential directions in a manner that they surround a circumference surface area around the LED, and has continuous surfaces formed such that the boundary portions of the convex surfaces constitute concave surfaces.

The light emitting surface is formed in such a manner that the boundary portion of concave surfaces is formed with a continuous surface so as to form a convex surface, so that the boundary area (see the boundary area 300a in FIG. 8 and FIG. 9) which affects the emitting direction of light on the boundary portion of the plurality of convex surfaces can be eliminated. Therefore, diffuse reflection and unintended diffusion cannot be caused, the light distribution as designed can be achieved and the extraction efficiency can be improved.

In addition, because the unintended light diffusion is not caused, an LED light distribution lens can be easily designed.

Further, in case of forming the light emitting surface with a mold, the mold is simply constructed with a continuous surface in such a manner that the boundary portion of the convex surfaces forms a concave surface, so that the mold is designed not to have an edge portion, thereby enabling to inexpensively produce a mold and to achieve low cost product. Still further, a defective molded product because of abrasion of mold can be inhibited and the mold life-span can be elongated.

Further according to the present invention, the convex surfaces formed in the circumferential direction of the light emitting surface and the concave surfaces of the light emitting surface are formed such that the concaves and the convexes are formed in reverse relation each other at substantially regular interval in its sectional view.

When each of the concave and the convex formed in the circumferential direction on the light emitting surface are formed so as to be reversed condition each other, the light emission angle from the light emitting surface having the same inclined angle can be equal and the nonuniform emission from the entire light emitting surface can be inhibited.

Still further, according to the present invention, the convex surface formed in the radial direction of the light emitting surface and the concave surfaces of the light emitting surface are formed such that the difference in height between their tops of the convex surfaces and their bottoms of the concave surfaces is larger at the outward area than the inward area in its radial direction in sectional view.

In such a case, the light emitted from the light emitting surface can be controlled and a wide light distribution without nonuniform emission can be achieved. Namely, when the difference in height between the top of the convex surface and the bottom of the concave surface is made larger into outward in radial direction, the light refraction (spread) can be larger into outward in radial direction.

The LED lighting module of the present invention comprises an LED; a substrate on which the LED is mounted; and a module body in which the LED light distribution lenses as mentioned above are provided in the arrangement of plural lines. Further, the light equipment of the present invention is provided with the LED lighting module as mentioned above.

### ADVANTAGEOUS EFFECTS

According to the present invention, the designed light distribution can be achieved, the diffuse reflection and unintended diffusion cannot be caused, and the light extraction efficiency can be improved. In addition, the cost for producing the mold for the light emitting surface can be reduced, thereby reducing the production cost.

### BRIEF DESCRIPTION OF DRAWINGS

FIG. 1 is an entire perspective view of one embodiment of the LED light distribution lens of the present invention.

FIG. 2 is an entire perspective view showing the 3D image of the LED light distribution lens.

FIG. 3 is a fragmentary sectional view taken in the direction of the arrows substantially along the line X-X of FIG. 1.

FIG. 4a is a fragmentary sectional view taken in the direction of the arrows substantially along the line Y-Y of FIG. 1, and FIG. 4b is an enlarged view of the light emitting surface shown in FIG. 3.

FIG. 5a and FIG. 5b are partially enlarged views for explaining the configuration of the light emitting surface of the LED light distribution lens.

FIG. 6 shows an embodiment of an LED lighting module having the LED light distribution lens shown in FIG. 1, FIG. 6a is a perspective view of the light emitting surface seen from the front and FIG. 6b is a perspective view of the light emitting surface seen from the back.

FIG. 7 is an embodiment of lighting equipment having the LED lighting module shown in FIG. 6 and shows a perspective view of the embodiment attached on a ceiling.

FIG. 8 is an entire perspective view of an embodiment of the prior LED light distribution lens.

FIG. 9 is a schematic view for explaining the problems of the prior LED light distribution lens, FIG. 9a shows an ideal mold and the sectional view of the cell of the LED light distribution lens formed with the mold, and FIG. 9b is an actual mold and the sectional view of the cell of the LED light distribution lens formed with the mold.

### BEST MODE FOR CARRYING OUT THE INVENTION

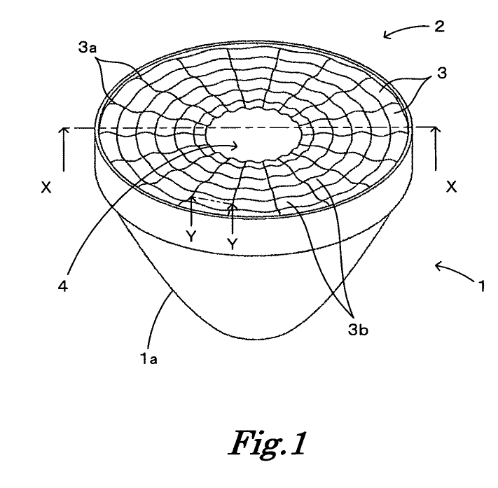

Now an embodiment of the present invention is explained based on FIG. 1-FIG. 8.

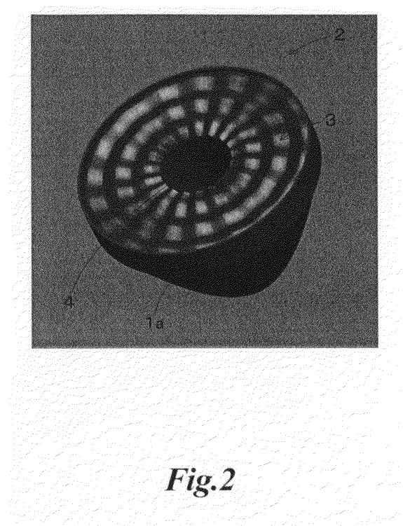

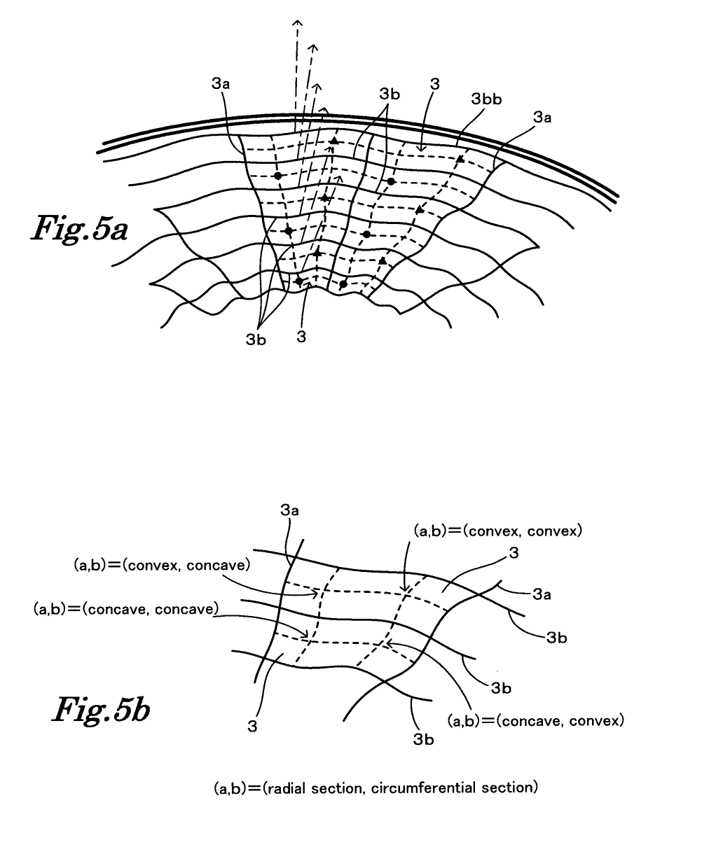

Lines such as 3a, 3b are indicated on a light emitting surface 2, which are mentioned hereinafter, in FIG. 1 and FIG. 5, however, they are not actually formed on the light emitting surface 2 and they are only shown for representation and explanation of the configuration (concave-convex surface) of the light emitting surface 2. FIG. 2 is a 3D image showing the LED light distribution lens of the present invention.

An LED light distribution lens 1 is made of a transparent acrylic material and the like and is formed like a mortar of conic shape of which circular portion is formed upward, as shown in FIG. 1 and FIG. 2.

The upper face of the LED light distribution lens 1 has the light emitting surface 2 which is circular in plan view and emits the light from an LED 6 forward. The light emitting surface 2 is formed with a continuous surface in a manner such that a plurality of convex surfaces are formed in the radial direction and in the circumferential direction around the LED 6 which is a light source provided at the center and that the boundary portion of the convex surfaces forms a gentle concave surface as shown in FIG. 1 and FIG. 2. Namely, not only the radial direction of the light emitting surface 2 is two-dimensionally formed in convex and concave, but also the concavo-convex shape is continuously formed without seam in three-dimensionally in the radial direction and the circumferential direction.

It is difficult to represent such a concave-convex continuous face in the radial direction and the circumferential direction in plan view, so that the light emitting surface 2 in FIG. 1 and FIG. 5 is divided in such a manner that one concave or one convex formed in the radial direction is set as a unit, one concave formed in the circumferential direction and one convex formed continuously are set as a unit, and the lines 3a, 3b are indicated in the radial direction and the circumferential direction. However, the light emitting surface 2 is formed with a surface of continuous concave and convex without having any uneven structures like a groove as shown in the 3D image in FIG. 2.

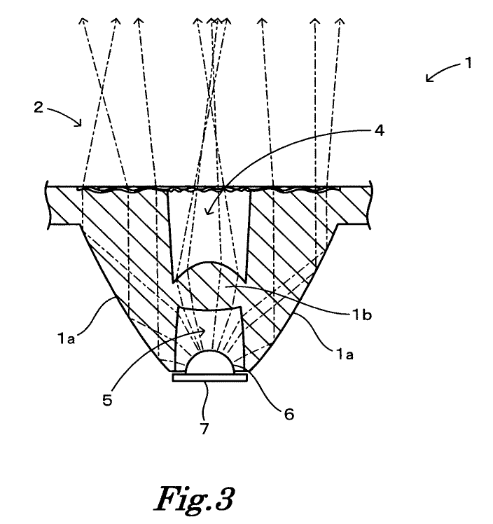

As shown in FIG. 3, the center of the bottom of the LED light distribution lens 1 has the LED 6 (light emitting diode) and the LED 6 is mounted on a substrate 7 having a control portion (not shown) for executing on-off control. An LED recess 5 is provided so as to efficiently emit the light from the LED 6 at the center on a convex lens 1b provided directly above the LED 6 or on a critical reflection surface 1a.

A central recess 4 is formed at the center of the light emitting surface 2 and the convex lens 1b is provided between the LED recess 5 and the central recess 4. The surface of the convex lens 1b is formed in convex so as to emit the light transmitting therethrough without causing nonuniform emission.

The inclined surface like a mortar forms the critical reflection surface 1a reflecting the light from the LED 6 into the light emitting surface 2 and is designed to have an angle capable of reflecting the light emitted from the LED 6 to be emitted from the light emitting surface 2.

The size of the LED light distribution lens 1 is not specifically limited, however, when the diameter of the light emitting surface 2 is from 16.3 mm to 17.2 mm, the distance from the upper face of the substrate 7 to the upper face of the LED light distribution lens 1 may be preferably 12.6 mm to 13.6 mm and the diameter of the opening of the LED recess 5 and the central recess 4 may be preferably 4.7 mm to 5.7 mm.

In FIG. 3 the light path emitted from the light emitting surface 2 via the critical refraction surface 1a is shown with one-dotted lines, and the light path of the light emitted via the convex lens 1b is shown with two-dotted lines.

The light emitted from the side of the LED 6 reflects on the critical reflection surface 1a and is emitted into the light emitting surface 2 as shown with one-dotted lines. When the light from the LED 6 transmits the light emitting surface 2, the refraction degree (spread degree) of the light is differed depending on the emitting portion on the light emitting surface 2 as shown with one-dotted lines, thereby achieving a wide light distribution without nonuniform emission. More detailed explanation will be given later.

The convex lens 1b is designed in a manner such that the light from the LED 6 transmitting the convex lens 1b is emitted forward without transmitting the light emitting surface 2 and that the outer side of the lens 1b has a larger output angle so as to be refracted using the refraction phenomenon as shown with two-dotted liens in FIG. 3. In addition, the convex lens 1b is designed such that the light transmitting the inner side of the convex lens 1b has a smaller output angle.

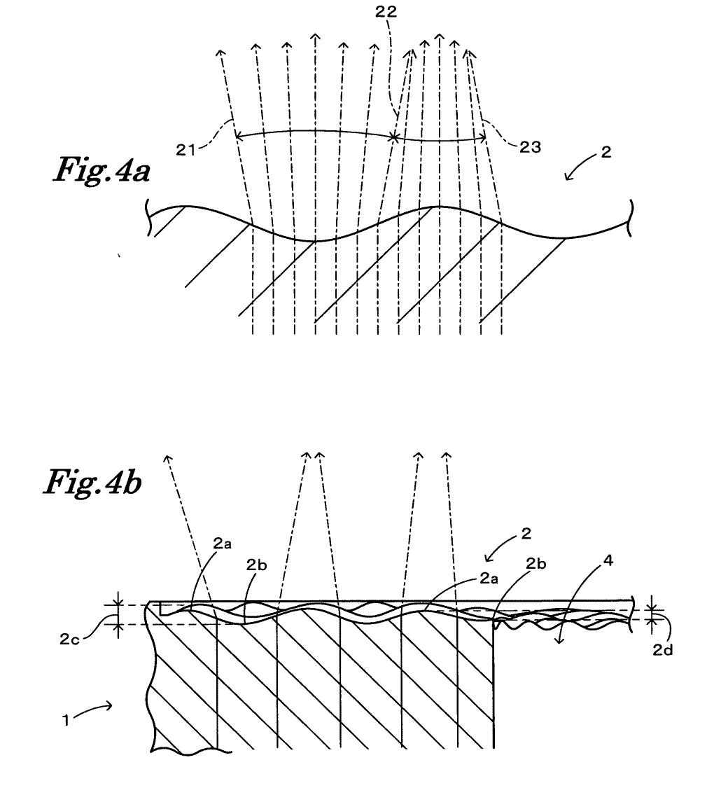

FIG. 4a is a fragmentary sectional view taken in the direction of the arrows substantially along the line Y-Y of FIG. 1 and the light emitting surface 2 is partially enlarged for explanation.

On the convex surface and the concave surface of the light emitting surface 2 formed in the circumferential direction, the concavo-convex shape is repeated with a substantially regular interval and the concave shape and the convex shape are formed in reversed condition each other in sectional view.

By such a configuration, the output angles of the light emitted from the convex surface and the concave surface which are formed continuously in the circumferential direction in sectional view can be made equal (refer to the one-dotted lines in FIG. 4a). Namely, a plurality of the convex surfaces and a plurality of concave surfaces having the same inclined angle are formed, and light is emitted from the inclined surfaces with the same angle on the light path 21 at left, the central light path 22, and the light path 23 at right facing the sheet of FIG. 4a, so that the output angles become equal. Such a face is continuously formed, so that the output angle of the light emitted from the light emitting surface 2 having the same inclined angle becomes accordingly equal.

FIG. 4b is a partial enlarged view of FIG. 3

The reference numeral 2a in the figure indicates a top portion having the highest convex on the convex surface and the reference numeral 2b indicates a lowest bottom portion on the concave surface.

On the convex surface and the concave surface formed in the radial direction on the light emitting surface 2, the concavo-convex shape is repeated with substantially equal spaces in such a manner that the height difference of the top portion 2a of the convex surface and the bottom portion 2b of the concave surface is made larger into outward in the radial direction.

The height difference between the outermost top portion 2a on the convex surface in the radial direction and the outermost bottom portion 2b on the concave surface in the radial direction is represented with the reference numeral 2c and the height difference between the innermost top portion 2a on the convex surface in the radial direction and the innermost bottom portion 2b on the concave surface in the radial direction is represented with the reference numeral 2d, wherein the relation of 2c and 2d is 2c>2d.

The light emitting surface 2 is thus formed, so that when the difference in height between the top of the convex surface and the bottom of the concave surface is made larger into outward in the radial direction, the light refraction (spread) can be larger into outward in the radial direction. The difference becomes smaller inward in the radial direction, so that light with small refraction can be emitted.

The configuration of the light emitting surface 2 is more detailed referring to FIG. 5.

In FIG. 5a and FIG. 5b, as mentioned above, the light emitting surface 2 is divided in such a manner that one concave or one convex formed in the radial direction is set as a unit in the radial direction, one concave formed in the circumferential direction and the convex formed continuously are set as a unit in the circumferential direction, the lines 3a, 3b are indicated in the radial direction and the circumferential direction, and the area divided by the lines 3a, 3b is set as a unit area 3 of the light emitting surface 2 for easy explanation. The reference numeral 3bb in the figure shows a concavo-convex line in the outermost diameter. Dotted lines are indicated so as to show the top portion of the convex surface and the bottom portion of the concave surface and the triangular mark painted with black shows the highest top of the convex surface and the circular mark painted with black shows the lowest portion of the concave surface.

The concavo-convex shape of the light emitting surface 2 is determined by calculating and designing in such a manner that light refracts at an optional angle on the concave-convex shape in the radial direction in sectional plan. For example, the sectional shape of the line 3a shown with a bold line among the lines 3a in FIG. 5a is determined.

Further, the concavo-convex shape is calculated and designed in such a manner that light refracts at an optional angle on the concavo-convex line 3bb in the circumferential direction.

Then while forming the concavo-convex surface which is determined in the radial direction in sectional plan, the concavo-convex shape which is determined in the circumferential direction is swept while forming concavo-convex roll in up and down around the center of the circular light emitting surface 2 in plan view.

FIG. 5b is a partial enlarged view of the light emitting surface 2 in FIG. 5a in which the section in the radial direction is represented with “a”, the section in the circumferential direction is represented with “b”, the case when the section is formed in a concave surface is represented with “concave” and the case when the section is formed in a convex surface is represented with “convex”.

Watching thus formed light emitting surface 2 per each emitting surface unit area 3, for example, the unit area 3 formed inside in the radial direction (forward on the sheet) in FIG. 5b is formed with the concave surface and the convex surface in the circumferential direction in sectional view (namely; “b” is concave and convex) and is formed with the concave surface in the radial direction in sectional view (namely “a” is concave).

Further, for example, the unit area 3 formed outside in the radial direction (back on the sheet) in FIG. 5b is formed with the convex surface and the concave surface in the circumferential direction in sectional view (namely, “b” is convex and concave), contrary to the convex and concave of the unit area 3 in inside of the radial direction, and is formed with the convex surface in the radial direction in sectional view (namely “a” is convex).

The light path emitted from thus formed light emitting surface 2 per the unit area 3 is as follows.

The one-dotted line in FIG. 5a represents the light path emitted from the light emitting surface 2 and this light path shows that of the emitted light when the position of the line 3b is shown in sectional plan.

The concave-convex shape in the circumferential direction in sectional plan becomes gentle into outward in the circumferential direction, so that the output angle of the light path becomes smaller into outward in the circumferential direction, thereby reducing the refraction (spread) of the light.

On the other hand, the light path emitted when the position of the line 3a in the radial direction is seen in sectional plan is not shown, however, it is same as that shown in FIG. 4b.

Accordingly, when the difference in height between the top of the convex surface and the bottom of the concave surface is made larger into outward in the radial direction, the light refraction (spread) can be larger into outward in the radial direction. The difference becomes smaller inward in the radial direction, so that light with small refraction can be emitted.

As mentioned above, the light is emitted with large refraction or small refraction depending on the concave-convex shape formed on the convex surface and the concave surface, so that the expansion of the light transmitting the light emitting surface 2 becomes equal on the entire light emitting surface 2, thereby obtaining uniformly irradiating surface 2.

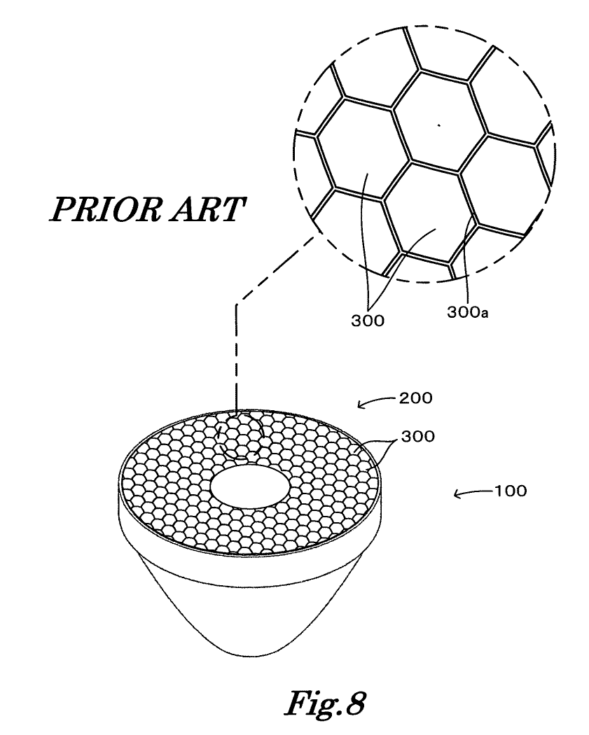

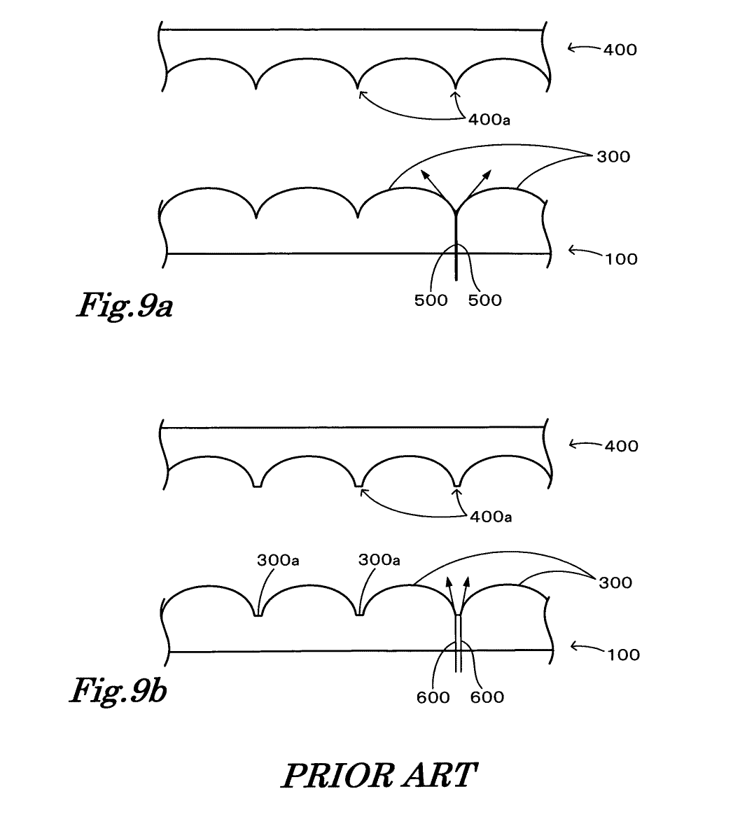

The boundary area which is apt to be formed in the prior process with a mold (see the boundary area 300a in FIG. 8 and FIG. 9) is not formed, so that the light distribution design can be facilitated and the damage caused by the light control can be reduced at minimum. Namely, the above-mentioned boundary area does not exist on the light emitting surface 2, so that the diffuse reflection and unintended diffusion caused by the boundary area cannot appear, the light distribution as designed can be achieved and the extraction efficiency can be improved.

In addition, when the light emitting surface 2 is formed with a mold, the mold is preferably constructed with a continuous surface in such a manner that the boundary portion of the convex surface forms a gentle concave surface and the is not provided with an edge portion, thereby enabling to inexpensively produce a mold and to achieving a low cost product. In addition, a defective molded product because of abrasion of mold can be inhibited and the mold life-span can be elongated.

Further, the light emitting surface 2 may be processed with emboss treatment (surface roughing process) in order to eliminate further nonuniform emission.

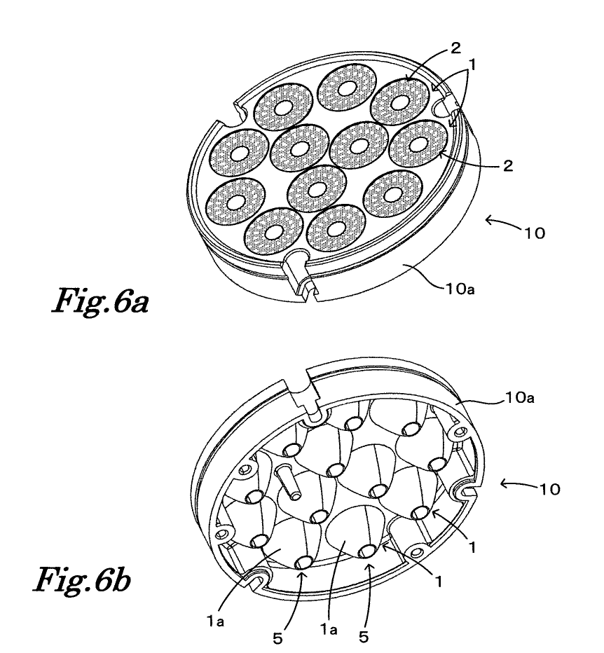

FIG. 6a and FIG. 6b show an embodiment of an LED lighting module having the above-mentioned LED light distribution lens, and the LED 6 and the substrate 7 are not shown in FIG. 6b for easy understanding.

The LED lighting module 10 comprises a module body 10a like a disc, a plurality of LED light distribution lenses 1, the LED 6 and the substrate 7.

The module body 10a has a plurality of recesses to which the LED light distribution lens 1 is assembled. The module body 10a in the figure is designed to be assembled with three LED light distribution lenses 1 at the center and nine LED light distribution lenses 1 so as to surround them.

As shown in FIG. 6b, in the back of the module body 10a, a plurality of critical reflecting surfaces 1a like mortar and a plurality of LED recesses 5 are revealed and the LED 6 is provided where the LED recess 5 is formed.

The structure of the LED lighting module 10 is not limited to that and the number of the LED light distribution lens 1 and the arrangement structure are not limited to that. For example, one LED light distribution lens 1 may be provided at the center and six LED light distribution lenses 1 may be provided therearound.

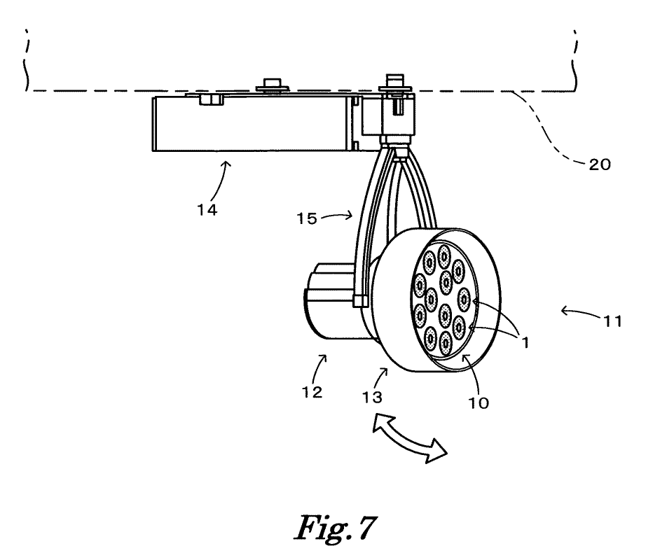

FIG. 7 is an embodiment of lighting equipment 11 having the LED lighting module 10 shown in FIG. 6. When the above-mentioned LED light distribution lens 1 is formed as the LED lighting module 10 to be incorporated into the lighting equipment 11, it can be used as a light source of lighting equipment.

The figure shows the lighting equipment 11 which is fixed on a ceiling 20 as a spot light, the lighting equipment 11 has a main body 12, a hood 13 covering the side of the LED lighting module 10, a case for power supply 14, an arm 15 supporting the main body 12, and the like, in which the lighting equipment 11 is designed to change the output angle while supported with the arm 15 (refer to an outlined arrow in the figure).

Accordingly, the lighting equipment 11 can achieve light distribution as designed without causing nonuniform emission, low power consumption, and long life utilizing the characteristic of the LED 6.

The structure of the lighting equipment 11 is not limited to that mentioned above, and it can be used as the light source for a downlight and a ceiling light.

1. An LED light distribution lens for emitting forward light of an LED disposed in the center thereof, said lens having a light emitting surface with a circular shape in plan view,
wherein said light emitting surface has a plurality of convex surfaces both in its radial and its circumferential directions in a manner that they surround a circumference surface area around said LED,
and has continuous surfaces formed such that the boundary portions of said convex surfaces constitute concave surfaces.

2. The LED light distribution lens as set forth in claim 1, wherein said convex surfaces formed in the circumferential direction of said light emitting surface and said concave surfaces of said light emitting surface are formed such that the concaves and the convexes are formed in reverse relation each other at substantially regular interval in its sectional view.

3. The LED light distribution lens as set forth in claim 1, wherein said convex surface formed in the radial direction of said light emitting surface and said concave surfaces of said light emitting surface are formed such that the difference in height between their tops of said convex surfaces and their bottoms of said concave surfaces is larger at the outward area than the inward area in its radial direction in sectional view.

4. The LED light distribution lens as set forth in claim 2, wherein said convex surface formed in the radial direction of said light emitting surface and said concave surfaces of said light emitting surface are formed such that the difference in height between their tops of said convex surfaces and their bottoms of said concave surfaces is larger at the outward area than the inward area in its radial direction in sectional view.

5. An LED lighting module, comprising:
an LED;
a substrate on which said LED is mounted; and
a module body in which said LED light distribution lenses as set forth in any one of claims 1-4 are provided in the arrangement of plural lines.

6. A light equipment in which said LED lighting module as set forth in claim 5 is mounted.
